(19) United States
(12) Patent Application Publication
(10) Pub. No.: US 2010/0117058 A1
(43) Pub. Date: May 13, 2010

(54) MULTI-STRUCTURE NANOWIRE AND METHOD OF MANUFACTURING THE SAME

(75) Inventors: Jong-Hyurk Park, Daejeon-city (KR); Sung-Lyul Maeng, Chungcheongbuk-do (KR); Rae-Man Park, Daejeon-city (KR); Andrea C. Ferrari, Cambridgeshire (GB); Andrea Fasoli, Cambridgeshire (GB); Alan Colli, Cambridgeshire (GB)

Correspondence Address: RABIN & Berdo, PC, 1101 14TH STREET, NW, SUITE 500, WASHINGTON, DC, 20005, US

(73) Assignee: ELECTRONICS AND TELECOMMUNICATIONS RESEARCH INSTITUTE, Daejeon-city (KR)

(21) Appl. No.: 12/532,645

(22) PCT Filed: Feb. 26, 2008
(86) PCT No.: PCT/KR08/01100

§ 371 Date: Sep. 23, 2009

(30) Foreign Application Priority Data
Apr. 11, 2007 (KR) 10-2007-0035723

(51) Int. Cl. H01L 29/12; H01L 21/20

(52) U.S. Cl. 257/14; 438/478; 257/E29.07; 257/E21.09; 977/762

(57) ABSTRACT

Provided is a multi-structure nanowire in which silicon nanowires are formed at both ends of a compound semi-conductor nanorod, and a method of manufacturing the multi-structure nanowire. The method includes providing a compound semiconductor nanorod; forming metal catalyst tips on both ends of the compound semiconductor nanorod; and growing silicon nanowires on both ends of the compound semiconductor nanorod where the metal catalyst tips are formed.

### TECHNICAL FIELD

The present invention relates to a semiconductor nanowire structure and a method of manufacturing the same, and more particularly, to a multi-structure of nanorods of a compound semiconductor and silicon nanowires and a method of manufacturing the multi-structure nanowire.

The present invention was supported by the Information Technology (IT) Research & Development (R & D) program of the Ministry of Information and Communication (MIC) [project No. 2005-S-605-02, project title: IT-BT-NT Convergent Core Technology for advanced Optoelectronic Devices and Smart Bio/Chemical Sensors].

### BACKGROUND ART

Nano-structures such as nanowires or nanorods have been intensively studied in the last decade due to their new electrical, catalytic, and optical characteristics. Nanowires have a diameter of a few tens of nanometers and have no limit in length, and nanorods have the same diameters as the nanowires and generally have a length of three to five times of the diameter thereof. Basic characteristics of nanowires and nanorods can be varied by simply changing the dimensions thereof while chemical compositions thereof are maintained constant. Such nano-structures have intermediate characteristics between a molecule and a bulk shape. For example, a nano-structure based on a semi-conductor material shows a three-dimensional quantum confinement phenomenon in both electrons and holes, and this phenomenon results in the increase in an effective band gap of a material together with a reduction in size of the nano-structure. Accordingly, as the size of the nano-structure is reduced, optical absorption and emission of the nano-structure is biased towards blue light. As another example, when a nanowire has a multi-layer structure, the nanowire can be further effectively used as an optical device or an electron device. A nanowire having a structure in which doping concentration is controlled in an axis direction or a nanowire formed of different materials is known as a multi-structure nanowire.

However, despite the high functional potential of the nano-structures, only a few applied products have been developed. One of the reasons for this is due to the difficulty of producing nano-structures. It is even more difficult to produce a multi-structure nanowire. If it is possible to produce a multi-structure nanowire, a functional device such as an ultra small optical device or a tunneling electronic device can be developed.

### DISCLOSURE OF INVENTION

### Technical Problem

To address the above and/or other problems, the present invention provides a multi-structure nanowire that can be used as an optical device or an electron device and a method of manufacturing the multi-structure nanowire.

### Technical Solution

According to an aspect of the present invention, there is provided a multi-structure nanowire in which silicon nanowires are junctioned at both ends of a compound semi-conductor nanorod.

The compound semiconductor may be one selected from the group consisting of AlN, AlP, AlAs, GaN, GaP, GaAs, InP, InAs, InSb, AlInGaP, AlGaAs, InGaN, CdS, CdSe, CdTe, ZnO, ZnS, ZnSe, ZnTe, TiO₂, HgTe, and CdHgTe.

The compound semiconductor nanorod may have a length of 2 to 100 nm and may have a diameter of 10 to 100 nm.

According to an aspect of the present invention, there is provided a method of manufacturing a multi-structure nanowire, comprising: providing a compound semi-conductor nanorod; forming metal catalyst tips on both ends of the compound semi-conductor nanorod; and growing silicon nanowires on both ends of the compound semiconductor nanorod where the metal catalyst tips are formed.

The compound semiconductor may be one selected from the group consisting of AlN, AlP, AlAs, GaN, GaP, GaAs, InP, InAs, InSb, AlInGaP, AlGaAs, InGaN, CdS, CdSe, CdTe, ZnO, ZnS, ZnSe, ZnTe, TiO₂, HgTe, and CdHgTe.

The compound semiconductor nanorod may have a length of 2 to 100 nm and may have a diameter of 10 to 100 nm.

The metal catalyst tips may comprise a material selected from the group consisting of Au, Ag, and Ni.

The growing silicon nanowires on the both ends of the compound semiconductor nanorod where the metal catalyst tips are formed may comprise: dispersing the compound semiconductor nanorods on a substrate; placing the substrate on which the compound semiconductor nanorod is dispersed in a chamber; and heat treating the chamber in a silicon source atmosphere to decompose the silicon source to silicon atoms or silicon molecules, whereby growing silicon nanowire on the both ends of the compound semiconductor nanorod.

The silicon source may comprise a mixture powder of Si and C or a silane gas SiH₄.

### Advantageous Effects

According to the present invention, metal catalyst tips are formed on both ends of a compound semiconductor nanorod, and silicon nanowires are grown from both ends of the compound semiconductor nanorod. Thus, a multi-structure nanowire comprising a compound semiconductor and silicon can be formed. A multi-structure nanowire formed in this way can be used in an optical device or an electron device.

### DESCRIPTION OF DRAWINGS

The above and other features and advantages of the present invention will become more apparent by describing in detail exemplary embodiments thereof with reference to the attached drawings in which:

FIG. 1 is a schematic perspective view of a multi-structure nanowire according to an embodiment of the present invention; and

FIGS. 2A through 2D are schematic drawings for explaining a method of manufacturing a multi-structure nanowire, according to an embodiment of the present invention.

### BEST MODE

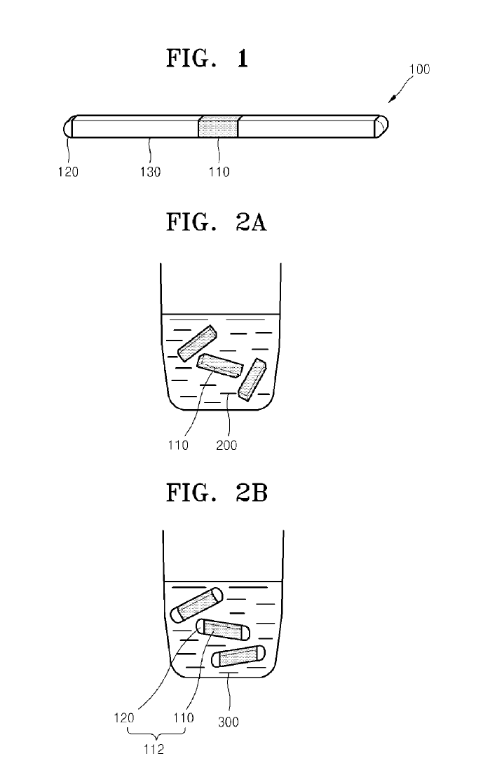

Referring to FIG. 1, the multi-structure nanowire 100 according to the current embodiment of the present invention has a structure in which silicon nanowires 130 are junctioned at both ends of a nanorod 110 formed of a compound semiconductor. The diameter of the multi-structure nanowire 100 may be 10 to 100 nm. The length of the nanorod 110 may be 2 to 100 nm, and the length of the silicon nanowires 130 can be controlled according to usage.

### Mode for Invention

The present invention will now be described more fully with reference to the accompanying drawings, in which exemplary embodiments of the invention are shown. The invention may, however, be embodied in many different forms and should not be construed as being limited to the embodiments set forth herein; rather, these embodiments are provided so that this disclosure will be thorough and complete, and will fully convey the concept of the invention to those skilled in the art. In the following descriptions, it is understood that when a layer is referred to as being ‘on’ another layer or substrate, it can be directly on the other constituent element, or intervening a third constituent element may also be present. Also, in the drawings, the thicknesses of layers and regions are exaggerated for clarity, and like reference numerals in the drawings denote like elements. Terminologies used in the descriptions are to explain the present invention, and do not confine the limit of meanings and the range of the present invention.

FIG. 1 is a schematic perspective view of a multi-structure nanowire 100 according to an embodiment of the present invention. Referring to FIG. 1, the multi-structure nanowire 100 according to the current embodiment of the present invention has a structure in which silicon nanowires 130 are junctioned at both ends of a nanorod 110 formed of a compound semiconductor. The diameter of the multi-structure nanowire 100 may be 10 to 100 nm. The length of the nanorod 110 may be 2 to 100 nm, and the length of the silicon nanowires 130 can be controlled according to usage.

The compound semiconductor used to form the nanorod 110 can be a Group III-V compound such as AlN, AlP, AlAs, GaN, GaP, GaAs, InP, InAs, InSb, AlInGaP, AlGaAs, or InGaN, or a Group II-VI compound such as CdS, CdSe, CdTe, ZnO, ZnS, ZnSe, ZnTe, TiO₂, HgTe, or CdHgTe. However, the compound semiconductor that can be used to from the nanorod 110 of the multi-structure nanowire 100 is not limited to the above materials.

As described above, since the multi-structure nanowire 100 has a structure in which the silicon nanowires 130 are formed at both ends of the nanorod 110, the applicability of the multi-structure nanowire 100 can be increased. For example, it may be difficult to combine a compound semiconductor nano-structure with a silicon-based device due to physical property differences between the compound semiconductor and silicon. However, since the silicon nanowires 130 are formed at both ends of the nanorod 110, it is easier to combine the nanorod 110 and a silicon-based device. The reference number 120 is a metal catalyst tips used for junctioning silicon nanowires 130 at the ends of the nanorod 110 and the metal catalyst tips 120 can be removed.

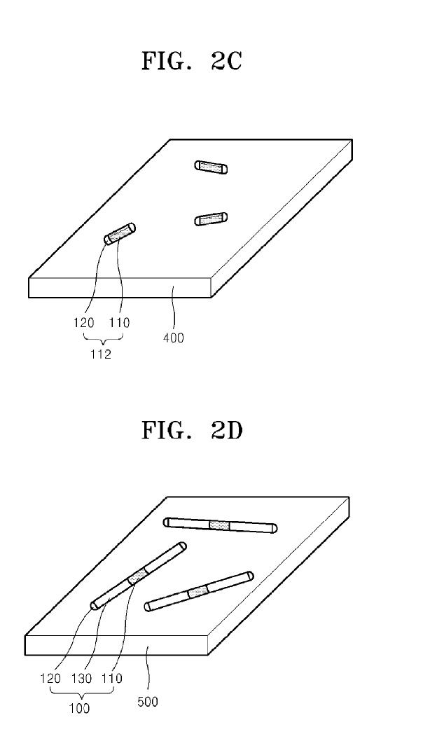

FIGS. 2A through 2D are schematic drawings for explaining a method of manufacturing a multi-structure nanowire, according to an embodiment of the present invention. In the present embodiment, a cadmium selenide is used to form a compound semiconductor nanorod. Referring to FIG. 2A, a cadmium selenide nanorod 110 is formed. The cadmium selenide nanorod 110 can be formed using a well-known wet method. In order to form the cadmium selenide nanorod 110, a mixture of dimethyl cadmium and tributylphosphine in which selenium powder is dissolved is mixed with a mixed solution 200 of trioctylphosphineoxide (TOPO) and tetradecylphosphonic acid. In this regard, the dimethyl cadmium and the tributylphosphine in which the selenium powder is dissolved are mixed in a ratio of 1.5:1. The mixed solution 200 of TOPO and tetradecylphosphonic acid may be maintained at a temperature of approximately 300° C. The diameter of the cadmium selenide nanorod 110 formed in this way is 10 to 100 nm. The length of the cadmium selenide nanorod 110 can be controlled by controlling the temperature and reaction time, and may be in a range of 2 to 100 nm. In particular, in order to be used as a nano-optical device, the length of the cadmium selenide nanorod 110 may be approximately 3 nm. In the present embodiment, cadmium selenide is used to form a nanorod; however, a material for forming the nanorod is not limited to cadmium selenide, and can be, for example, CdSe, CdTe, ZnO, TiO₂, GaO, SiC, ZnS, or CdS.

Referring to FIG. 2B, metal catalyst tips 120 are formed on both ends of the cadmium selenide nanorod 110. The metal catalyst tips 120 can be formed of Au. In order to form the metalcatalyst tips 120 formed of Au, the cadmium selenide nanorod 110 and Aucl₃ are immersed in a mixed solution 300 of toluene, dodecyldimethylammonium, and dodecylamine, and the mixture is stirred. In this manner, nanorods 112 having hemisphere-shaped Au catalyst tips on both ends thereof can be formed. Meanwhile, the metal catalyst tips 120 can be formed of Ag, Ni, Pt, Pd, Cu, Co, Ir, Ro, or Ru, besides Au.

Referring to FIG. 2C, the mixed solution 300 in which the nanorods 112 having the metal catalyst tips 120 is immersed, is dispersed on a substrate 400 formed of a material such as silicon using a method such as spin coating. Afterwards, the mixed solution 300 is evaporated, leaving the nanorods 112 remaining on the substrate 400.

Referring to FIG. 2D, the substrate 400 on which the nanorods 112 are dispersed is moved to a chamber in which silicon nanowires can be formed, and silicon nanowires 130 are grown on both ends of the nanorods 112. A silicon raw material for forming the silicon nanowires 130 can be a Si+C powder or a silane gas SiH₄. In thermal decomposition of silicon atoms or molecules from a silicon raw material, a decomposition temperature of approximately 800° C. or greater is required when Si+C powder is used, and a decomposition temperature of approximately 300° C. or greater is required when silane gas is used. Silicon atoms or silicon molecules decomposed from a silicon raw material form a eutectic mixture on both ends of the nanorods 112, and if the silicon molecules are super-saturated, the silicon nanowires 130 grow.

In this way, as depicted in FIG. 1, a multi-structure nanowire 100 in which the cadmium selenide nanorod 110 is positioned in the center and the silicon nanowires 130 are formed on both ends of the cadmium selenide nanorod 110 is formed.

Meanwhile, after the silicon nanowires 130 are grown, the metal catalyst tips 120 remaining on both ends of the silicon nanowires 130 can be removed using a wet method.

According to the present invention, metal catalyst tips are formed on both ends of a compound semiconductor nanorod, and silicon nanowires are grown from both ends of the compound semiconductor nanorod. Thus, a multi-structure nanowire comprising a compound semiconductor and silicon can be formed. A multi-structure nanowire formed in this way can be used in an optical device or an electron device.

While the present invention has been particularly shown and described with reference to exemplary embodiments thereof, it will be understood by those of ordinary skill in the art that various changes in form and details may be made therein without departing from the spirit and scope of the present invention as defined by the following claims.

1. A multi-structure nanowire in which silicon nanowires are junctioned at both ends of a compound semiconductor nanorod.

2. The multi-structure nanowire of claim 1, wherein the compound semiconductor is one selected from the group consisting of AlN, AlP, AlAs, GaN, GaP, GaAs, InP, InAs, InSb, AlInGaP, AlGaAs, InGaN, CdS, CdSe, CdTe, ZnO, ZnS, ZnSe, ZnTe, TiO₂, HgTe, and CdHgTe.

3. The multi-structure nanowire of claim 1, wherein the compound semiconductor nanorod has a length of 2 to 100 nm.

4. The multi-structure nanowire of claim 1, wherein the multi-structure nanowire has a diameter of 10 to 100 nm.

5. A method of manufacturing a multi-structure nanowire, comprising:
providing a compound semiconductor nanorod;
forming metal catalyst tips on both ends of the compound semiconductor nanorod; and
growing silicon nanowires on both ends of the compound semiconductor nanorod where the metal catalyst tips are formed.

6. The method of claim 5, wherein the compound semiconductor is one selected from the group consisting of AlN, AlP, AlAs, GaN, GaP, GaAs, InP, InAs. InSb, AlInGaP, AlGaAs, InGaN, CdS, CdSe, CdTe, ZnO, ZnS, ZnSe, ZnTe, Ti0₂, HgTe, and CdHgTe.

7. The method of claim 5, wherein the compound semiconductor nanorod has a length of 2 to 100 nm.

8. The method of claim 5, wherein the multi-structure nanowire has a diameter of 10 to 100 nm.

9. The method of claim 5, wherein the metal catalyst tips comprise a material selected from the group consisting of Au, Ag, and Ni.

10. The method of claim 5, wherein the growing silicon nanowires on the both ends of the compound semiconductor nanorod comprises:
dispersing the compound semiconductor nanorod on a substrate;
placing the substrate on which the compound semiconductor nanorod is dispersed in a chamber; and
heat treating the chamber in a silicon source atmosphere to decompose the silicon source to silicon atoms or silicon molecules, whereby growing silicon nanowire on the both ends of the compound semiconductor nanorod.

11. The method of claim 10, wherein the silicon source comprises a mixture powder of Si and C or a silane gas SiH₄.

12. The method of claim 10, wherein the heat treating is performed in the range of 300° C. to 800° C.
